(19) United States
(12) Patent Application Publication
(10) Pub. No.: US 2022/0405250 A1
(43) Pub. Date: Dec. 22, 2022

(54) DATA PROCESSING DEVICE, DATA PROCESSING PROGRAM, AND DATA PROCESSING METHOD

(71) Applicant: RETAIL AI, INC., Tokyo (JP)

(72) Inventor: Guofeng JIAO, Fukuoka (JP)

(21) Appl. No.: 17/779,340

(22) PCT Filed: Nov. 27, 2019
(86) PCT No.: PCT/JP2019/046368

§ 371 Date: May 24, 2022

(51) Int. Cl. G06F 16/174

(52) U.S. Cl. CPC G06F 16/1744

(57) ABSTRACT

A device (1) for processing transaction data (D1) including a plurality of records includes: a storage unit (2) that stores the transaction data; and a compressed data generation unit (5) configured to generate compressed data (D6) corresponding to the transaction data, based on a value of a transaction quantity included in the transaction data stored in the storage unit (2), wherein each of the records includes a value of at least one item, the item includes the transaction quantity, and the value of the transaction quantity includes a natural number other than 1.

### TECHNICAL FIELD

The present invention relates to a data processing device, a data processing program, and a data processing method.

### BACKGROUND ART

A retail store generates and accumulates transaction data every time a transaction occurs, such as selling a product to a customer, placing an order with a supplier, and purchasing a product from a supplier. For example, every time a retail store sells a product to a customer, the retail store generates and accumulates sales data including information for identifying a customer, a product, a sales price, and the like, and performs sales management, product inventory management, product order management, customer purchase analysis, or the like, based on the accumulated sales data. The enormous number of sales data is generated in a supermarket with a large number of products for sale and a large number of customers purchasing products, especially in a chain store that operates a large number of stores.

When the enormous number of sales data is accumulated or calculated at high speed for analysis, hardware resources of a large-scale computer are required. For this reason, it is necessary to enhance efficiency of data processing such as data compression and restoration by compressing and accumulating the enormous number of data so as to reduce data capacity, or restoring (also referred to as decompressing, expanding, extracting, and the like) compressed data for high-speed calculation.

A method of compressing the enormous number of data has been proposed (for example, see PTL 1).

### CITATION LIST

### Patent Literature

[PTL 1] JP2008-287723 A

### SUMMARY OF INVENTION

### Technical Problem

An object of the present invention is to provide a data processing device, a data processing program, and a data processing method capable of enhancing efficiency of data processing.

### Solution to Problem

The present invention is a data processing device for processing transaction data including a plurality of records, the data processing device including: a storage unit that stores the transaction data; and a compressed data generation unit configured to generate compressed data corresponding to the transaction data, based on a value of a transaction quantity included in the transaction data stored in the storage unit, wherein each of the records includes a value of at least one item, the item includes the transaction quantity, and the value of the transaction quantity includes a natural number other than 1.

### Advantageous Effects of Invention

The present invention is able to enhance efficiency of data processing.

### BRIEF DESCRIPTION OF DRAWINGS

FIG. 1 is a block diagram illustrating an embodiment of a data processing device according to the present invention.

FIG. 2 is a schematic diagram illustrating relations among data to be processed by the data processing device according to the present invention.

FIG. 3 is another schematic diagram illustrating the relations among data to be processed by the data processing device according to the present invention.

FIG. 4 is still another schematic diagram illustrating the relations among data to be processed by the data processing device according to the present invention.

FIG. 5 is a schematic diagram illustrating an example of compression target data to be processed by the data processing device according to the present invention.

FIG. 6 is a schematic diagram illustrating an example of the compression target data in FIG. 5 after sorting processing.

FIG. 7 is a schematic diagram illustrating an example of partial data to be processed by the data processing device according to the present invention.

FIG. 8 is a schematic diagram illustrating an example of compressed partial data to be processed by the data processing device according to the present invention.

FIG. 9 is a schematic diagram illustrating another example of the compressed partial data to be processed by the data processing device according to the present invention.

FIG. 10 is a schematic diagram illustrating still another example of the compressed partial data to be processed by the data processing device according to the present invention.

FIG. 11 is a schematic diagram illustrating an example of dictionary data to be processed by the data processing device according to the present invention and FIG. 11A is a customer ID dictionary, FIG. 11B is a date dictionary, and FIG. 11C is a receipt order dictionary.

FIG. 12 is a schematic diagram illustrating an example of index data to be processed by the data processing device according to the present invention and FIG. 12A is an offset value of a compression block and FIG. 12B is an offset value of a dictionary block.

FIG. 13 is a schematic diagram illustrating a data structure of compressed data to be processed by the data processing device according to the present invention.

FIG. 14 is a flowchart illustrating an embodiment of a data processing method according to the present invention.

FIG. 15 is a flowchart illustrating an example of partial data generation processing included in the data processing method according to the present invention.

FIG. 16 is a flowchart illustrating an example of compressed partial data generation processing included in the data processing method according to the present invention.

FIG. 17 is a flowchart illustrating an example of compressed data generation processing included in the data processing method according to the present invention.

FIG. 18 is a table illustrating an example of a compression rate by the data processing method according to the present invention.

### DESCRIPTION OF EMBODIMENTS

Hereinafter, embodiments of a data processing device, a data processing program, and a data processing method according to the present invention are described with reference to the drawings.

Herein, the data processing device according to the present invention described below is described using a case where compressed data is generated by performing compression processing (processing for reducing data capacity) with respect to data to be compressed (hereinafter referred to as “compression target data”). In other words, the compression processing is an example of the data processing in the present invention.

Note that the data processing in the present invention may include, for example, restoration processing for restoring all or part of the compression target data from the compressed data other than the compression processing for generating the compressed data from the compression target data.

### Configuration of Data Processing Device

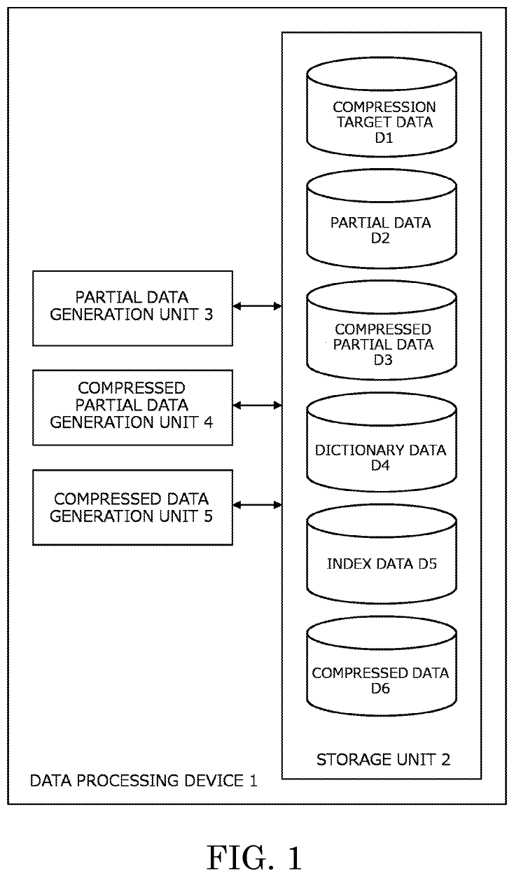

FIG. 1 is a block diagram illustrating an embodiment of a data processing device (hereinafter referred to as “present device”) according to the present invention.

A present device 1 includes a storage unit 2, a partial data generation unit 3, a compressed partial data generation unit 4, and a compressed data generation unit 5.

The present device is implemented by an information processing device such as a personal computer. In the present device, a data processing program (hereinafter referred to as “present program”) according to the present invention operates, cooperates with hardware resources of the present device, and implements a data processing method (hereinafter referred to as “present method”) according to the present invention described later.

The hardware resources of the present device 1 include, for example, a processor such as a central processing unit (CPU), a micro processing unit (MPU), or a digital signal processor (DSP). The processor executes an instruction described in the present program, thereby implementing the above-described means (the partial data generation unit 3, the compressed partial data generation unit 4, and the compressed data generation unit 5) included in the present device 1.

Note that causing an unillustrated computer to execute the present program allows the computer to function in the same manner as the present device and execute the present method.

The storage unit 2 stores the present program and information necessary for the present device 1 to execute the present method. The storage unit 2 is constituted of, for example, a hard disk drive (HDD), a solid state drive (SSD), a random access memory (RAM), a semiconductor memory element such as a flash memory, and the like.

The information stored in the storage unit 2 includes compression target data D1, partial data D2, compressed partial data D3, dictionary data D4, index data D5, and compressed data D6. A structure of each data and other details are described later.

The partial data generation unit 3 generates the partial data D2 from the compression target data D1.

The compressed partial data generation unit 4 generates the compressed partial data D3, the dictionary data D4, and the index data D5 from the partial data D2.

The compressed data generation unit 5 generates the compressed data D6 from the compressed partial data D3, the dictionary data D4, and the index data D5.

### Structure of Data

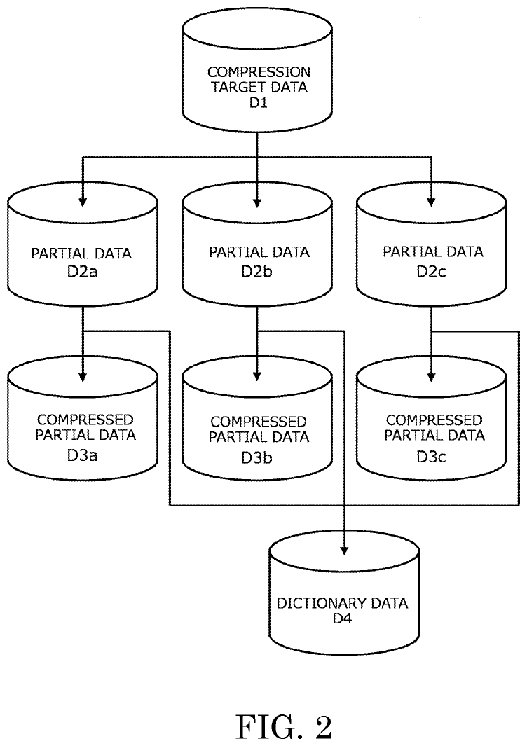

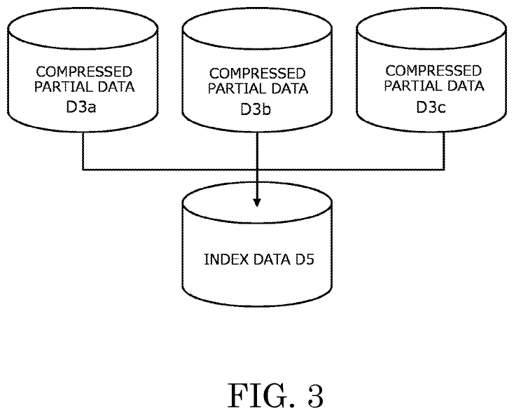

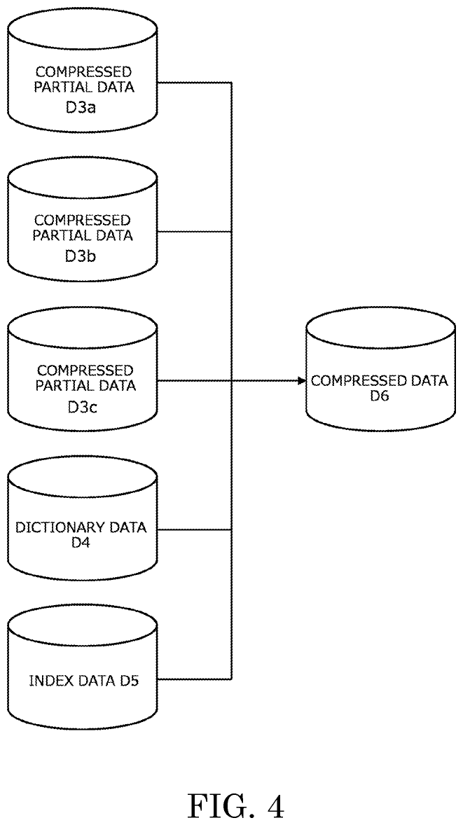

FIG. 2, FIG. 3, and FIG. 4 are schematic diagrams illustrating relations among a plurality of pieces of data to be processed by the present device.

FIG. 2 illustrates that partial data D2a, partial data D2b, and partial data D2c are generated from the compression target data D1.

FIG. 2 illustrates that compressed partial data D3a is generated from the partial data D2a, compressed partial data D3b is generated from the partial data D2b, and compressed partial data D3c is generated from the partial data D2c.

FIG. 2 illustrates that the dictionary data D4 is generated from the partial data D2a, the partial data D2b, and the partial data D2c.

FIG. 3 illustrates that the index data D5 is generated from the compressed partial data D3a, the compressed partial data D3b, and the compressed partial data D3c. (More specifically, the index data D5 is generated based on a data length of each compressed partial data D3).

FIG. 4 illustrates that the compressed data D6 is generated from the compressed partial data D3a, the compressed partial data D3b, the compressed partial data D3c, the dictionary data D4, and the index data D5.

### Compression Target Data

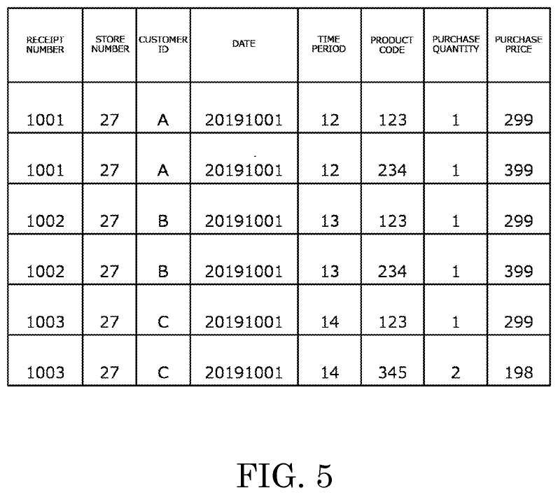

FIG. 5 is a schematic diagram illustrating an example of the compression target data D1. Herein, the compression target data D1 in the present embodiment is sales data (receipt data) of a retail store. Note that the compression target data in the present invention may be, for example, transaction data including a transaction quantity of products between traders. The sales data of a retail store is an example of the transaction data including sales quantity of products between the retail store and a customer of the retail store. As the transaction data, for example, order data including an order quantity of products between a retail store and a supplier of the retail store, or purchase data including a purchase quantity of products between the retail store and a supplier of the retail store may be used. The transaction quantity of products between traders is, for example, a natural number, and includes a natural number other than 1. In some retail stores, the same product may be sold in units of 3 (¼ dozen), in units of 6 (half dozen) or in units of 12 (1 dozen). In this case, the transaction quantity includes a multiple of 3 or a multiple of 6.

A file format of the compression target data D1, each of the data D2, D3, D4, D5, and D6 to be processed by the present device 1 is a text format.

FIG. 5 illustrates that the compression target data D1 includes a plurality of records (6 records) arranged in an order of issuing receipts.

FIG. 5 illustrates that items of data constituting each record are “receipt number”, “store number”, “customer ID”, “date”, “time period”, “product code”, “purchase quantity”, and “purchase price”.

FIG. 5 illustrates that, for example, in a record of the first line, pieces of information on the receipt number “1001”, the store number “27”, the customer ID “A”, the date “20191001”, the time period “12”, the product code “123”, the purchase quantity “1”, and the purchase price “299” are stored in the storage unit 2 in association with one another.

Herein, storing the pieces of information in the storage unit 2 in association with one another means that the information is stored in the storage unit 2 in such a way that the present device 1 can search and retrieve other information from any information (hereinafter, the same idea applies). That is, for example, the present device 1 can use the receipt number “1001” and retrieve, from the storage unit 2, the store number “27” stored in association with the receipt number “1001”.

FIG. 5 illustrates that a customer with customer ID “A” purchased “1 unit” of a product with product code “123” at “299 yen” between “12:00 and 13:00” on “Oct. 1, 2019” at a store with store number “27”. FIG. 5 also illustrates that, at the same time, the same customer with customer ID “A” purchased “1 unit” of a product with product code “234” at “399 yen” at the same store. Further, FIG. 5 illustrates that the products purchased by the customer with customer ID “A” are 2 units of the products described above, the purchase history is managed by the store with the receipt of the same receipt number “1001”, and these information is printed on, for example, the receipt provided to the customer from the store.

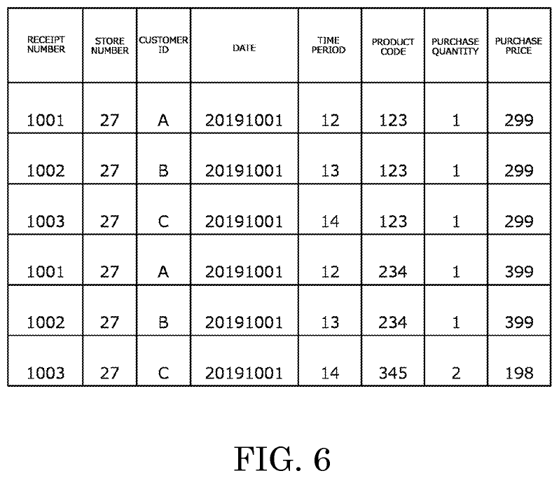

FIG. 6 is a schematic diagram illustrating an example of the compression target data D1 after the plurality of records are sorted based on a value of a division item among the plurality of items constituting the record of the compression target data D1. The division item is the “product code”. FIG. 6 illustrates that the six records are sorted in an ascending order of the product code (Note that, in the present embodiment, the store numbers of the six records are the same “27,” and thus there is no change in the order of the records before and after the sorting processing with the value of the store number.). Specific processing details of the sorting processing are described later.

Herein, the value of each item constituting the record is a numerical value or a character string.

Partial Data

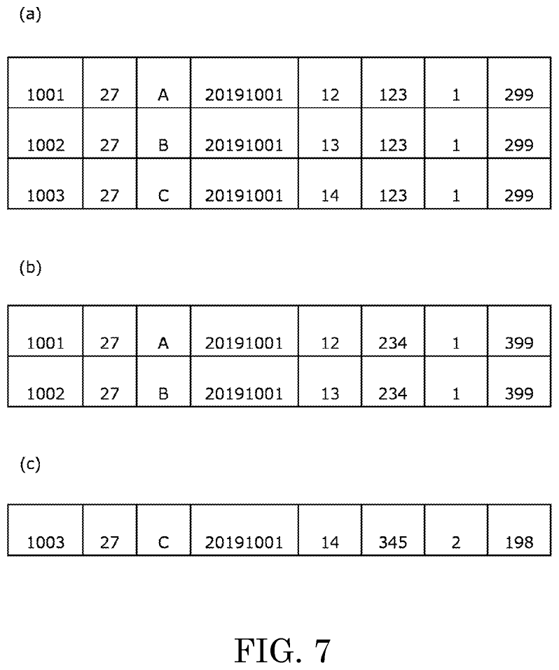

FIG. 7 is a schematic diagram illustrating an example of the partial data D2. The partial data D2 is data generated by dividing the plurality of records included in the compression target data D1 for each record having a common value of the division item (that is, dividing the compression target data D1 in units of the records). In other words, the values of the division items of all records included in the partial data D2 are common (same). Each of the divided and generated partial data D2 includes one or more records.

FIG. 7 illustrates that the compression target data D1 is divided into three pieces of partial data, and FIG. 7A is the partial data D2a with product code “123”, FIG. 7B is the partial data D2b with product code “234”, and FIG. 7C is the partial data D2c with product code “345”.

### Compressed Partial Data

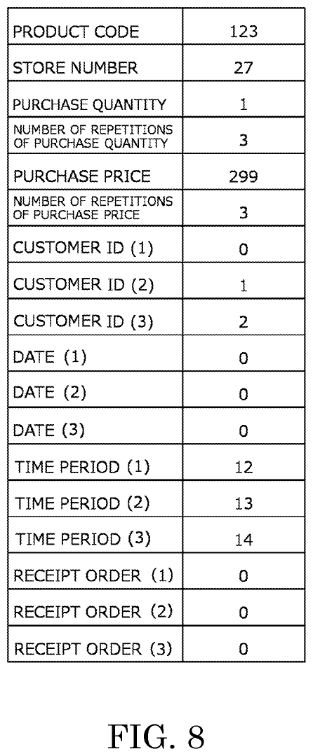

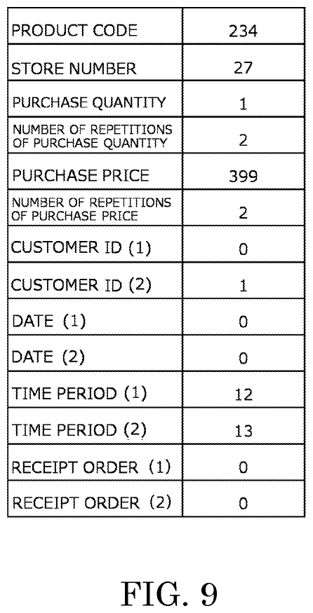

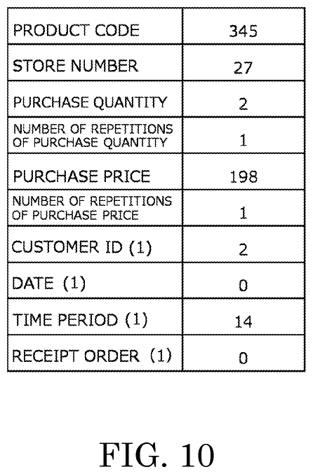

FIG. 8, FIG. 9, and FIG. 10 are schematic diagrams illustrating examples of the compressed partial data D3, and FIG. 8 illustrates an example of the compressed partial data D3a, FIG. 9 illustrates an example of the compressed partial data D3b, and FIG. 10 illustrates an example of the compressed partial data D3c.

The compressed partial data D3 is data to be generated for each partial data D2, based on a value of a compression item among the items included in the partial data D2. More specifically, the compressed partial data D3 is generated for each partial data D2, based on the number of records having the same value of the compression item among the records included in the partial data D2. The compression item is the “purchase quantity” among the plurality of items constituting the records of the compression target data D1.

Herein, the value of the “purchase quantity” is a natural number. That is, the “purchase quantity” includes a natural number other than “1”. In addition, the value of the “purchase quantity” includes a natural number such as “6” indicating a half dozen, or “12” or “18” being a multiple of 6. In other words, the value of the “purchase quantity” included in sales data of a retail store that sells a product in half a dozen units (or in units of “6”) is a multiple of “6.”

The compressed partial data D3 includes a dictionary value determined for each value of the dictionary item instead of the value of the dictionary item included in the partial data D2. In other words, in the compressed partial data D3, the value of the dictionary item is replaced with the dictionary value. The dictionary items are “customer ID” and “date”. A data length of the dictionary value is shorter (smaller) than a data length of the value of the dictionary item. The value of the dictionary item and the corresponding dictionary value are stored in the storage unit 2 as the associated dictionary data D4.

For example, FIG. 8 illustrates that the information included in the compressed partial data D3a is, from the top of the data, the product code “123”, the store number “27”, the purchase quantity “1”, the number of repetitions of the purchase quantity “3”, the purchase price “299”, the number of repetitions of the purchase price “3”, the customer ID “0” of a first customer, the customer ID “1” of a second customer, the customer ID “2” of a third customer, the date “0” of the first customer, the date “0” of the second customer, the date “0” of the third customer, the time period “12” of the first customer, the time period “13” of the second customer, the time period “14” of the third customer, the receipt order “0” of the first customer, the receipt order “0” of the second customer, and the receipt order “0” of the third customer.

That is, FIG. 8 illustrates that the number of repetitions of the record of the purchase quantity “1” is “3” and the number of repetitions of the record of the purchase price “299” is “3” with respect to the product with product code “123” in the store with store number “27”. In other words, the partial data D2a illustrates that the partial data D2a includes three records indicating that 1 unit of the product has been purchased (sold) at 299 yen.

FIG. 8 illustrates that the dictionary value of the customer ID of the first customer is “0”, the dictionary value of the customer ID of the second customer is “1”, and the dictionary value of the customer ID of the third customer is “2” among the three customers who purchased the product. The dictionary value of the customer ID is described later.

FIG. 8 illustrates that the dictionary value of the date when the first customer purchased the product is “0”, the dictionary value of the date when the second customer purchased the product is “0”, and the dictionary value of the date when the third customer purchased the product is “0” among the three customers who purchased the product. The dictionary value of the date is described later.

FIG. 8 illustrates that the time period when the first customer purchased the product is “between 12:00 and 13:00”, the time period when the second customer purchased the product is “between 13:00 and 14:00”, and the time period when the third customer purchased the product is “between 14:00 and 15:00” among the three customers who purchased the product.

FIG. 8 illustrates that the dictionary value of the receipt order of the first customer is “0”, the dictionary value of the receipt order of the second customer is “0”, and the dictionary value of the receipt order of the third customer is “0” among the three customers who purchased the product. The dictionary value of the receipt order is described later.

### Dictionary Data

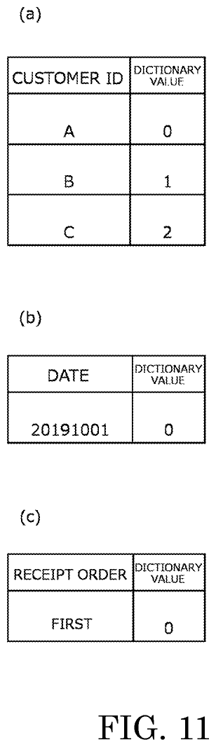

FIG. 11 is a schematic diagram illustrating an example of the dictionary data D4, and FIG. 11A is a customer ID dictionary, FIG. 11B is a date dictionary, and FIG. 11C is a receipt order dictionary.

The dictionary data D4 is commonly generated by the partial data D2a, the partial data D2b, and the partial data D2c.

Note that, in the present invention, the dictionary data may be generated for each partial data.

The customer ID dictionary is data including the dictionary value for each value of the customer ID. FIG. 11A illustrates that the customer ID “A” and the dictionary value thereof “0” are associated with each other, the customer ID “B” and the dictionary value thereof “1” are associated with each other, the customer ID “C” and the dictionary value thereof “2” are associated with each other, and these are stored as the customer ID dictionary. The compressed partial data generation unit 4 determines the dictionary value for each value of a dictionary ID included in the partial data D2 when generating the compressed partial data D3 from the partial data D2.

The dictionary value for each value of the dictionary items is commonly generated by the partial data D2a, the partial data D2b, and the partial data D2c. That is, for example, the dictionary value “0” of the customer ID “A” included in the partial data D2a is also the dictionary value of the customer ID “A” included in the partial data D2b.

The date dictionary is data including the dictionary value for each value of date. FIG. 11B illustrates that date “20191001” and the dictionary value thereof “0” are associated with each other and are stored as the date dictionary. The compressed partial data generation unit 4 determines the dictionary value for each value of date included in the partial data D2 when generating the compressed partial data D3 from the partial data D2.

The receipt order dictionary is data including an order of the receipt number for each customer ID among the records included in the partial data D2. FIG. 11C illustrates that the receipt order “first” and the dictionary value thereof “0” are associated with each other and are stored as the receipt order dictionary. The compressed partial data generation unit 4 determines the dictionary value by specifying the order of the receipt number of the receipts for each customer ID among the records included in the partial data D2 when generating the compressed partial data D3 from the partial data D2.

For example, the partial data D2a illustrated in FIG. 7A includes three records, and the first record is a first record (receipt) of the customer with customer ID “A” in the partial data D2a, the second record is a first record (receipt) of the customer with customer ID “B” in the partial data D2a, and the third record is a first record (receipt) of the customer with customer ID “C” in the partial data D2a. Further, in the receipt order dictionary of the dictionary data D4 illustrated in FIG. 11C, the dictionary value corresponding to the receipt order “first” is “0”. Thus, in the compressed partial data D3a illustrated in FIG. 8, the dictionary value of the receipt order of the first customer is “0”, the dictionary value of the receipt order of the second customer is “0”, and the dictionary value of the receipt order of the third customer is “0” among the three customers who purchased the product with product code “123” at the store with store number “27”.

As described above, in the present embodiment, the dictionary value is commonly generated by the three pieces of compressed partial data. Thus, for example, as illustrated in FIG. 7, the dictionary value of the date “20191001” included in the partial data D2a, D2b, and D2c is “0” as illustrated in FIG. 11B. Therefore, in any of the compressed partial data D3a, D3b, and D3c illustrated in FIG. 8, FIG. 9, and FIG. 10, the date “20191001” is replaced with the common dictionary value “0”.

### Index Data

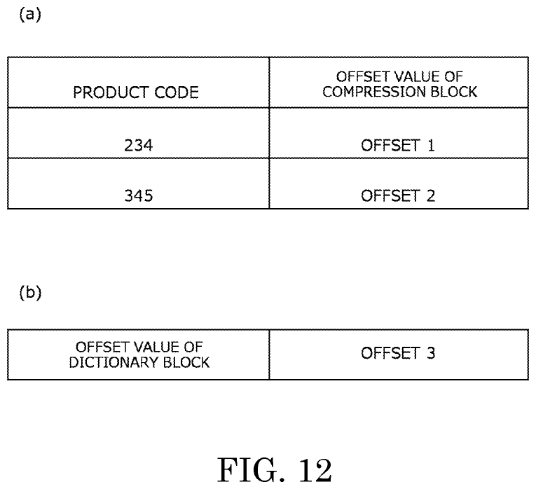

FIG. 12 is a schematic diagram illustrating an example of the index data D5. The index data is information indicating a start position of the compressed partial data D3 and a start position of the dictionary data D4 in the compressed data D6, that is, an offset value from a predetermined position of the compressed data D6 (a head position of the compressed data D6 in the present embodiment).

The present device 1 refers to the index data D5 when executing restoration processing of retrieving all or part of the specific partial data from the compressed data D6.

The index data D5 includes the offset value from the head of the compressed data D6 for each compressed partial data D3 and an offset value of the dictionary data D4 from the head of the compressed data D6.

The offset value from the head of the compressed data D6 for each compressed partial data D3 is stored as the index data D5 in association with a combination of the value of the division item, that is, the information specifying the compressed partial data D3. In other words, the offset value for each compressed partial data D3 is stored in association with the “product code” being the division item. FIG. 12A illustrates that the product code “234” and the offset value “OFFSET 1” are stored in association with each other. Similarly, FIG. 12B illustrates that the product code “345” and the offset value “OFFSET 2” are stored in association with each other.

Note that the compressed partial data D3a is arranged at the head of the compressed data D6, and thus the index data D5 does not include the offset value of the compressed partial data D3a. A reason for this is that, when retrieving the partial data D2a corresponding to the compressed partial data D3a, the present device 1 only needs to retrieve the compressed partial data D3a from the head of the compressed data D6.

The offset value for each compressed partial data D3 is calculated based on the data length of each compressed partial data D3. That is, an offset value of the compressed partial data D3b is calculated based on a data length of the compressed partial data D3a. An offset value of the compressed partial data D3c is calculated based on the sum of the data length of the compressed partial data D3a and a data length of the compressed partial data D3b.

The offset value of the dictionary data D4 from the head of the compressed data D6 is calculated based on a data length of a compression block, that is, the sum of the data length of the compressed partial data D3a, the data length of the compressed partial data D3b, and a data length of the compressed partial data D3c.

As described above, the index data D5 generated in the present embodiment includes the offset value of the compressed partial data D3b from the head of the compressed data D6, the offset value of the compressed partial data D3c from the head of the compressed data D6, and the offset value of the dictionary data D4 from the head of the compressed data D6.

FIG. 12 illustrates that the offset value “OFFSET 1” of the compressed partial data D3b, the offset value “OFFSET 2” of the compressed partial data D3c, and the offset value “OFFSET 3” of the dictionary data are calculated (generated) as the index data D5.

### Compressed Data

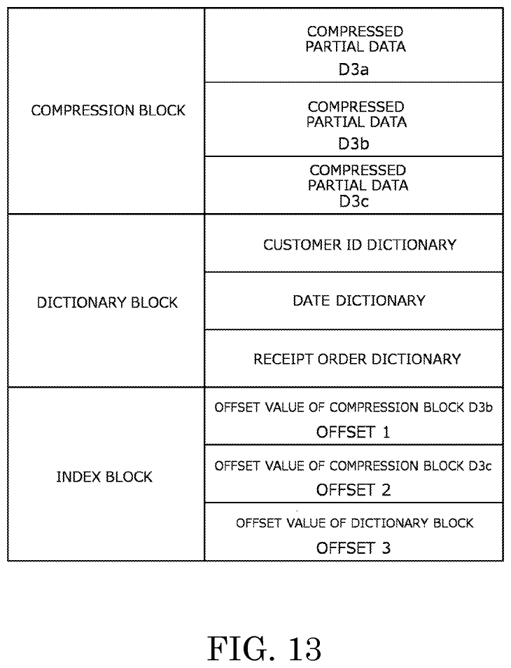

FIG. 13 is a schematic diagram illustrating an example of a data structure of the compressed data D6. The compressed data D6 is constituted by combining the compression block, a dictionary block, and an index block. The compression block is arranged at the head of the compressed data D6, then the dictionary block is arranged, and then the index block is arranged.

The compression block is constituted by combining the compressed partial data D3a, D3b, and D3c. The compressed partial data D3a is arranged at the head of the compression block, then the compressed partial data D3b is arranged, and then the compressed partial data D3c is arranged.

The dictionary block is constituted by combining the customer ID dictionary, the date dictionary, and the receipt order dictionary. The customer ID dictionary is arranged at the head of the dictionary block, then the date dictionary is arranged, and then the receipt order dictionary is arranged.

The index block is constituted by combining the offset value of the compressed partial data D3b, the offset value of the compressed partial data D3c, and the offset value of the dictionary data D4. The offset value of the compressed partial data D3b is arranged at the head of the index block, then the offset value of the compressed partial data D3c is arranged, and then the offset value of the dictionary data D4 is arranged.

### Data Processing Method

Next, an embodiment of the present method is described.

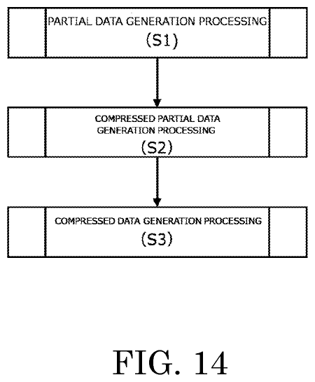

FIG. 14 is a flowchart illustrating the embodiment of the present method.

First, the present device 1 performs partial data generation processing by using the partial data generation unit 3 (S1). The partial data generation processing is information processing for generating the partial data D2 from the compression target data D1.

Next, the present device 1 performs compressed partial data generation processing by using the compressed partial data generation unit 4 (S2). The compressed partial data generation processing is information processing for generating the compressed partial data D3 for each partial data D2 from the partial data D2. The compressed partial data generation processing also includes information processing for generating the dictionary data D4 in the process of generating the compressed partial data D3. The compressed partial data generation processing includes information processing for generating the index data D5 from the generated compressed partial data D3.

Next, the present device 1 performs compressed data generation processing by using the compressed data generation unit 5 (S3). The compressed data generation processing is information processing for generating the compressed data D6 from the compressed partial data D3, the dictionary data D4, and the index data D5.

### Partial Data Generation Processing (S1)

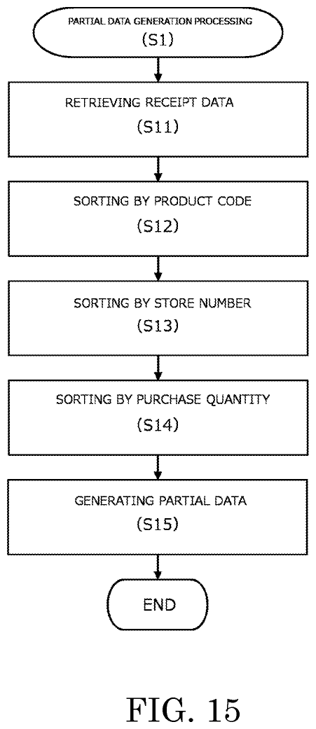

Next, the partial data generation processing is described. FIG. 15 is a flowchart illustrating an example of the partial data generation processing.

First, the present device 1 retrieves the receipt data (see FIG. 5) being the compression target data D1 (S11).

Next, the present device 1 sorts the receipt data by the product code, that is, rearranges a storage order (arrangement order) of the records in the data, based on the value of the product code included in each record (S12). The sorting order by the product code is, for example, an ascending order of the value of the product code.

Next, the present device 1 sorts, by the store number, the receipt data sorted by the product code (S13). The sorting order by the store number is, for example, an ascending order of the value of the store number.

Next, the present device 1 sorts, by the purchase quantity, the receipt data sorted by the product code and the store number (S14). The sorting order by the purchase quantity is, for example, an ascending order of the value of the purchase quantity.

Next, the present device 1 generates the plurality of pieces of partial data D2 (see FIG. 7) by dividing the receipt data (see FIG. 6) sorted by the product code, the store number, and the purchase quantity for each record having a common “product code” being the division item (S15).

### Compressed Partial Data Generation Processing (S2)

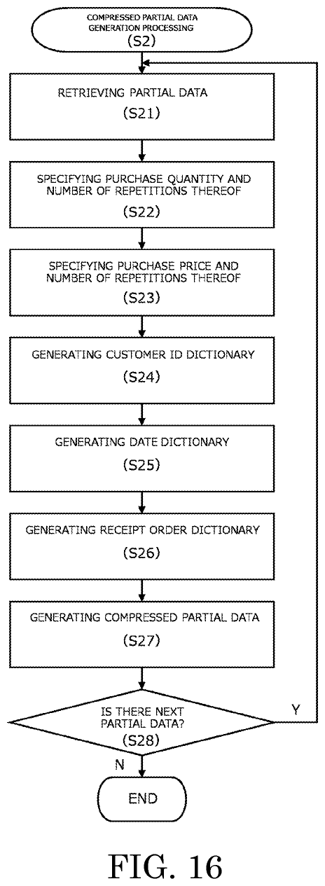

Next, the compressed partial data generation processing is described. FIG. 16 is a flowchart illustrating an example of the compressed partial data generation processing.

First, the present device 1 retrieves one piece of the partial data D2 (e.g., the partial data D2a) among the plurality of pieces of partial data D2 (S21). The compressed partial data generation processing is performed for each partial data, and the compressed partial data generation processing in the present embodiment is performed in an order of the partial data D2a, the partial data D2b, and the partial data D2c.

Next, the present device 1 sequentially retrieves the value of the purchase quantity included in the record (sorted by the value of the purchase quantity) constituting the partial data D2 from the first record of the partial data D2, and specifies the consecutive number of the records having a common value of the purchase quantity, that is, the number of repetitions of the records having the common value of the purchase quantity (S22).

Next, the present device 1 sequentially retrieves the value of the purchase price included in the records constituting the partial data D2 from the first record of the partial data D2, and specifies the consecutive number of the records having a common value of the purchase price, that is, the number of repetitions of the records having the common value of the purchase price (S23).

Next, the present device 1 determines the dictionary value for each value of the “customer ID” being the dictionary item included in the records constituting the partial data D2, and generates the customer ID dictionary (S24).

In determining the dictionary value of the customer ID, a plurality of candidate values of the dictionary value is stored in advance in the storage unit 2, and the present device 1 selects and determines a dictionary value which is not selected as the dictionary value from among the candidate values.

For example, “0”, “1”, “2” are stored in the storage unit 2 as the candidate values of the dictionary value of the customer ID. In the process of performing the compressed partial data generation processing for the partial data D2a illustrated in FIG. 7A, the present device 1 retrieves the customer ID “A” from the first record of the partial data D2a.

The present device 1 refers to the storage unit 2 and determines whether the customer ID dictionary is stored, and when determining that the customer ID dictionary is not stored, the present device 1 determines the candidate value “0” as the dictionary value of the customer ID “A”, generates a customer ID dictionary in which the customer ID “A” and the dictionary value “0” are associated, and stores the customer ID dictionary in the storage unit 2.

Next, the present device 1 retrieves the customer ID “B” from the second record of the partial data D2a. The present device 1 refers to the storage unit 2 and determines whether the customer ID dictionary is stored, and determines that the customer ID dictionary is stored. The present device 1 refers to the customer ID dictionary stored in the storage unit 2, determines whether the dictionary value of the customer ID “B” is stored, determines that the dictionary value of the customer ID “B” is not stored, determines the candidate value “1” as the dictionary value of the customer ID “B”, adds, to the customer ID dictionary, the customer ID “B” and the dictionary value “1” in association with each other, and updates and stores the contents of the customer ID dictionary.

Next, similarly, when the present device 1 retrieves the customer ID “C” from the third record of the partial data D2a, the present device 1 stores the customer ID “C” in association with the dictionary value “2” in the customer ID dictionary.

Further, in the process of performing the compressed partial data generation processing for the partial data D2b illustrated in FIG. 7B, the present device 1 retrieves the customer ID “A” from a first record of the partial data D2b. When the present device 1 refers to the storage unit 2 and determines that the dictionary value of the customer ID “A” is already stored in the customer ID dictionary, the present device 1 does not determine the dictionary value (the dictionary value “0” already stored in the customer ID dictionary is applied).

The same information processing is repeated in the following process and the customer ID dictionary common to all the partial data D2 is completed.

Next, the present device 1 determines a dictionary value for each value of “date” being the dictionary item included in the records constituting the partial data D2, and generates the date dictionary (S25).

In the same way as the method of determining the dictionary value of the customer ID described above, the method of determining the dictionary value of the date is that a dictionary value for a first date value is selected from among the plurality of candidate values of the dictionary value stored in advance in the storage unit 2 and is determined as the dictionary value. The determined dictionary value is stored in the storage unit 2 as the date dictionary in association with the value of the dictionary item.

Next, the present device 1 specifies the order (receipt order) of the receipt numbers for each customer ID included in the records constituting the partial data D2, determines the dictionary value for each specified receipt order (first, second, third), and generates the receipt order dictionary (S26).

In the same way as the method of determining the dictionary value for each customer ID described above, the method of determining the dictionary value for each receipt order is that a dictionary value for the first receipt order is selected from among the plurality of candidate values of the dictionary value stored in advance in the storage unit 2 and is determined as the dictionary value. The determined dictionary value is stored in the storage unit 2 as the receipt order dictionary in association with the value (receipt order) of the dictionary item.

For example, “0”, “1”, “2” are stored in the storage unit 2 as the candidate values of the dictionary value of the receipt order. In the process of performing the compressed partial data generation processing for the partial data D2a illustrated in FIG. 7A, the present device 1 retrieves the customer ID “A” from the first record of the partial data D2a.

Next, the present device 1 specifies an order of the retrieved record of the customer ID “A” in the partial data D2a, that is, the record order. For example, each time a record is retrieved in order from the head of the partial data D2a, the present device 1 counts the value of the customer ID included in the retrieved record and determines the record order (first, second, third, . . . ). For example, when the first record of the partial data D2a is retrieved, the present device 1 determines that the record is the first record of the customer ID “A”, that is, the record order is “first”.

Next, the present device 1 refers to the storage unit 2 and determines whether the receipt order dictionary is stored, and when determining that the receipt order dictionary is not stored, the present device 1 determines the candidate value “0” as the dictionary value of the receipt order “first”, generates the receipt order dictionary in which the receipt order “first” and the dictionary value “0” are associated, and stores the generated receipt order dictionary in the storage unit 2.

Next, the present device 1 retrieves the customer ID “B” from the second record of the partial data D2a. The present device 1 specifies the record order “first” of the customer ID “B” in the partial data D2a. The present device 1 refers to the storage unit 2 and determines whether the record order dictionary is stored, and determines that the record order dictionary is stored. The present device 1 refers to the receipt order dictionary stored in the storage unit 2 and determines whether the dictionary value of the record order “first” is stored, the dictionary value is already stored, and thus the present device 1 does not determine the dictionary value (the dictionary value “0” already stored in the record order dictionary is applied).

Next, the present device 1 retrieves the customer ID “C” from the third record of the partial data D2a, the record order is “first” similarly to the second record, and accordingly the present device 1 does not determine the dictionary value as described above.

The same information processing is repeated in the following process and the receipt order dictionary common to all the partial data D2 is completed.

By performing the processing S21 to S28 described above, all values of the data items constituting the compressed partial data D3a illustrated in FIG. 8A are determined, and the compressed partial data D3a is generated (S27).

The present device 1 performs from the processing S21 to the processing S26 for all (partial data D2a, D2b, D2c) of the partial data D2 generated by the partial data generation processing (S2) (S28). As a result, the present device 1 generates the compressed partial data D3a, D3b, and D3c illustrated in FIG. 8, FIG. 9, and FIG. 10, and the dictionary data D4 illustrated in FIG. 11, and stores the above data in the storage unit 2. Further, the present device 1 specifics the data length of each of the compressed partial data D3a, D3b, and D3c, calculates (specifies), based on the data lengths, the index data D5, that is, the offset value of each of the compressed partial data D3b and D3c and the offset value of the dictionary block, and stores the index data D5 in the storage unit 2.

Note that the generation processing of the customer ID dictionary (S24), the generation processing of the date dictionary (S25), and the generation processing of the receipt order dictionary (S26) may be performed simultaneously. Further, the dictionary generation processing (S24 to S26), that is, the processing for determining the dictionary value of each dictionary may be performed simultaneously with the processing for specifying the purchase quantity and the number of repetitions thereof (S22) and the processing for specifying the purchase price and the number of repetitions thereof (S23). In other words, for example, the present device 1 may simultaneously perform all or part of the processing (S22 to S26) each time the record is retrieved in order from the head of the partial data D2.

### Compressed Data Generation Processing (S3)

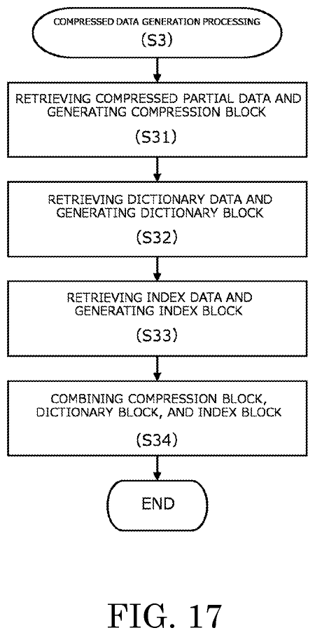

Next, the compressed data generation processing is described. FIG. 17 is a flowchart illustrating an example of the compressed data generation processing.

First, the present device 1 retrieves the compressed partial data D3 generated by the compressed partial data generation processing (S2) and stored in the storage unit 2, and generates the compression block (S31).

Next, the present device 1 retrieves the dictionary data D4 generated by the compressed partial data generation processing (S2) and stored in the storage unit 2, and generates the dictionary block (S32).

Next, the present device 1 retrieves the index data D5 generated by the compressed partial data generation processing (S2) and stored in the storage unit 2, and generates the index block (S33).

Next, the present device 1 combines the compression block, the dictionary block, and the index block, generates the compressed data D6 illustrated in FIG. 13, and stores the compressed data D6 in the storage unit 2 (S34).

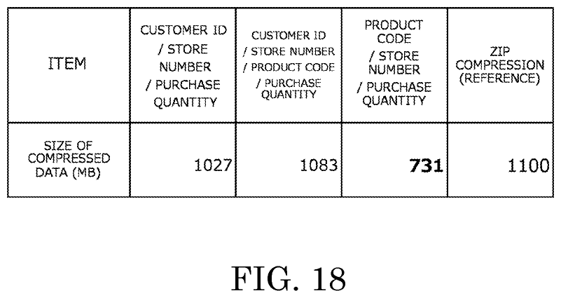

FIG. 18 is a table illustrating an example of a compression rate according to the present device 1. FIG. 18 illustrates a difference in capacity of generated compressed data, that is, a difference in a compression rate due to a difference in an order of items used for the sorting processing of the compression target data at the time of generating the partial data, when the same compression target data is compressed. The capacity of the compression target data in this example is 7 GB (gigabytes).

FIG. 18 illustrates that the data capacity of the compressed data is 1027 MB (megabytes) when the data is compressed by performing the sorting processing in an order of the “customer ID”, the “store number”, and the “purchase quantity”.

FIG. 18 illustrates that the data capacity of the compressed data is 1083 MB when the data is compressed by performing the sorting processing in an order of the “customer ID”, the “store number”, the “product code” and the “purchase quantity”.

In contrast, in the case of the present embodiment described above, that is, in the case of performing the sorting processing in an order of the “product code”, the “store number”, and the “purchase quantity” and compressing the data, FIG. 18 illustrates that the data capacity of the compressed data is 731 MB.

Noted that FIG. 18 illustrates as reference information that the data capacity of the compressed data is 1100 MB when the same compression target data is compressed using gunzip.

As described above, the compression rate varies depending on the items used in the sorting processing when the partial data is generated and the order of the items in which the sorting processing is performed. In addition, the compression rate varies depending on selection of the division item and the compression item among the items constituting the compression target data. Therefore, the compression rate increases (the capacity of the compressed data becomes smaller) by selecting the items used in the sorting processing, the order of the items in which the sorting processing is performed, or the division item and the compression item, in view of a characteristic (feature) of the value of each item included in the records constituting the compression target data. In other words, the compression rate increases by dividing the compression target data into the plurality of partial data (setting the division item) in such a way that the number of records having a common value of the item (compression item), namely, the number of repetitions of the value of the item (compression item) increases.

The compression target data D1 in the present embodiment is sales data (receipt data) of a retail store. According to a survey by the applicant, the number of units of a product (sales quantity) that an in-store customer purchases for each product is about 72.7% for one unit, about 17.3% for two units, about 4.3% for three units, and about 5.7% for four or more units. In other words, among the items included in the records constituting the compression target data D1, the item having the highest possibility of having the same value in each record is the “sales quantity”. Further, the sales price (purchase price) of the same product at the same store is usually the same except for discount sales. Therefore, after sorting the records included in the sales data in an order of the “product code”, the “store number”, and the “purchase quantity”, the compression target data D1 is divided into the plurality of pieces of partial data D2 using the “product code” as the division item, and then the compressed partial data D3 is generated from each of the pieces of partial data D2 using the “sales quantity” as the compression item, and thus the compression efficiency (data processing efficiency) is enhanced, that is, the reduction in capacity of the compressed data D6 is achieved.

Further, among the plurality of items included in the records constituting the compression target data D1, a value of an item that is neither division item nor compression item and is required to be restored from the compressed data D6 is replaced with a dictionary value having a short (small) data length and stored in the compressed data D6, and thus the compression efficiency of the compressed data D6 is enhanced.

Restoration Processing of Compression Data (Retrieving Partial Data from Compressed Data)

The present device 1 is able to retrieve each partial data D2a, D2b, and D2c from the compressed data D6.

Hereinafter, a case where the partial data D2b is retrieved, that is, a case where the sales data of the product with product code “234” is retrieved is described as an example.

First, the present device 1 retrieves the compressed data D6 stored in the storage unit 2.

Next, the present device 1 refers to the index block of the compressed data D6 and retrieves the offset value “OFFSET 1” of the compressed partial data D3b and the offset value “OFFSET 3” of the dictionary block. The present device 1 retrieves the offset value “OFFSET 1” of the compressed partial data D3b stored in the index block in association with the product code “234”. The present device 1 retrieves the offset value “OFFSET 3” of the dictionary block stored in the index block in association with predetermined information (information specifying the dictionary block) determined in advance.

Next, the present device 1 retrieves the compressed partial data D3b stored in a position of “OFFSET 1” from the head of the compressed data D6, and retrieves the dictionary data D4 stored in a position of “OFFSET 3” from the head of the compressed data D6.

Next, the present device 1 refers to the dictionary data D4, specifies a value of the dictionary item corresponding to the dictionary value included in the compressed partial data D3b, replaces the dictionary value with the value of the dictionary item, and generates the partial data D2b from the compressed partial data D3b.

In this way, the present device 1 restores and retrieves the partial data D2b from the compressed data D6.

However, the partial data D2b restored from the compressed data D6 and generated by the present device 1 does not include a value of the item “receipt number” included in the compression target data D1. In other words, the present device 1 restores (generates) only a part of the partial data D2b from the compressed data D6. A reason for this is that, as illustrated in FIG. 7 to FIG. 10, the compressed partial data D3 generated in the compressed partial data generation processing does not include information (the value itself or the dictionary value thereof) corresponding to the value of the “receipt number” included in the partial data D2. In other words, the present device 1 generates the compressed partial data D3 by omitting the value of the “receipt number” from the partial data D2. In this way, the value of the item that does not need to be included in the partial data restored from the compressed data is omitted in the compressed partial data generation processing, and thus the reduction in the capacity of the compressed data D6 is achieved.

Note that the present device 1 is also able to simultaneously retrieve each of the partial data D2a, D2b, and D2c from the compressed data D6. In other words, the present device 1 retrieves, for example, the offset value of the compressed partial data D3b and the offset value of the compressed partial data D3c from the index block, retrieves the compressed partial data D3b and D3c together with the compressed partial data D3a stored at the head of the compression block, and simultaneously performs the restoration processing of each compressed partial data. As a result, the present device 1 restores the values of a part of the data items of the partial data D2a, D2b, and D2c, and retrieves the partial data D2a, D2b, and D2c.

### CONCLUSION

According to the embodiment described above, in the compression processing of the compression target data D1, the present device 1 divides the compression target data D1 into the plurality of pieces of partial data D2, and then generates the compressed partial data D3 by compressing each piece of partial data D2. The present device 1 combines the plurality of pieces of compressed partial data D3 and generates the compressed data D6. The present device 1 generates the partial data D2, based on the division item (product code) included in the compression target data D1. The present device 1 compresses the partial data D2, based on the number of repetitions of the record having the same value of the compression item (purchase quantity) included in the partial data D2. The present device 1 compresses the partial data D2, based on the number of repetitions of the item (purchase price) having a common value in the records having the same value of the compression item. Therefore, the division item and the compression item are selected from among the plurality of items, in view of the characteristic (feather) of the value of each item included in the records constituting the compression target data D1, and thus the compression efficiency of the compression processing by the present device 1 is enhanced.

Further, the present device 1 replaces a value of an item that is neither the division item nor the compression item among the items included in the records constituting the compression target data D1 with a dictionary value having a data length shorter (smaller) than a data length of the above value, and generates the compressed data D6. Therefore, the compression efficiency of the compression processing by the present device 1 is further enhanced.

Meanwhile, in the restoration processing of the compressed data D6, the present device 1 is able to selectively retrieve all or part of the plurality of pieces of partial data D2 included in the compressed data D6 by referring to the index data D5. In other words, the present device 1 is able to restore only desired partial data D2 from the compressed data D6, and thus the restoration efficiency of the restoration processing by the present device is high.

Further, the present device 1 is able to simultaneously restore the plurality of pieces of partial data D2 from the compressed data D6, and thus the restoration efficiency of the restoration processing by the present device 1 is high.

Hereinafter, the features of the present device, the present program, and the present method described above are collectively described.

### (Feature 1)

A data processing device for processing transaction data including a plurality of records, the data processing device including:

a storage unit (e.g., the storage unit 2) that stores the transaction data; and
a compressed data generation unit (e.g., the compressed data generation unit 5) configured to generate compressed data corresponding to the transaction data, based on a value of a transaction quantity included in the transaction data stored in the storage unit, wherein
each of the records includes a value of at least one item,
the item includes the transaction quantity, and
the value of the transaction quantity includes a natural number other than 1.

### (Feature 2)

The data processing device according to Feature 1, wherein the value of the transaction quantity includes a multiple of 6.

### (Feature 3)

The data processing device according to Feature 1, wherein the compressed data generation unit generates the compressed data, based on the number of the records having the same value of the transaction quantity among the records included in the transaction data.

### (Feature 4)

The data processing device according to Feature 3, wherein

the compressed data generation unit rearranges, in the transaction data, an order of storing the records included in the transaction data, based on the value of the transaction quantity, and

generates the compressed data, based on the number of repetitions of the records having the same value of the transaction quantity in the transaction data.

### (Feature 5)

The data processing device according to Feature 4, wherein

the plurality of items includes a dictionary item,

the compressed data generation unit determines a corresponding dictionary value for each value of the dictionary item included in the transaction data, and generates the compressed data by replacing the value of the dictionary item included in the transaction data with the corresponding dictionary value, and

a data length of the dictionary value is shorter than a data length of the corresponding value of the dictionary item.

### (Feature 6)

The data processing device according to Feature 1 further including:

a partial data generation unit (e.g., the partial data generation unit 3) configured to divide the transaction data into a plurality of partial data, based on a value of a product code included in the transaction data stored in the storage unit; and

a compressed partial data generation unit (e.g., the compressed partial data generation unit 4) configured to generate compressed partial data for each of the partial data, based on the value of the transaction quantity included in the partial data, wherein

the item includes the product code, and

the compressed data generation unit generates the compressed data, based on the compressed partial data.

### (Feature 7)

The data processing device according to Feature 6, wherein

the compressed partial data generation unit generates the compressed partial data for each of the partial data, based on the number of the records having the same value of the transaction quantity among the records included in the partial data.

### (Feature 8)

The data processing device according to Feature 7, wherein

the partial data generation unit rearranges, in the transaction data, the order of storing the records included in the transaction data, based on the value of the transaction quantity, and

the compressed partial data generation unit generates the compressed partial data, based on the number of repetitions of the records having the same value of the transaction quantity in the transaction data.

### (Feature 9)

A data processing program including causing a computer to function as the data processing device according to Feature 1.

### (Feature 10)

A data processing method executed by a device having a storage unit (e.g., the storage unit 2) storing transaction data including a plurality of records, the data processing method including the step of generating compressed data corresponding to the transaction data, based on a value of the transaction quantity included in the transaction data stored in the storage unit, wherein

each of the records includes a value of at least one item,

the item includes a transaction quantity, and

the value of the transaction quantity includes a natural number other than 1.

### (Feature 11)

A data processing device for processing compression target data including a plurality of records, the data processing device including:

a storage unit (e.g., the storage unit 2) that stores the compression target data;

a partial data generation unit (e.g., the partial data generation unit 3) configured to divide the compression target data into a plurality of partial data, based on a value of a division item included in the compression target data stored in the storage unit;

a compressed partial data generation unit (e.g., the compressed partial data generation unit 4) configured to generate compressed partial data for each of the partial data, based on a value of a compression item included in the partial data; and

a compressed data generation unit (e.g., the compressed data generation unit 5) configured to generate compressed data corresponding to the compression target data, based on the compressed partial data, wherein

each of the records includes a value for each of a plurality of items, and

the plurality of items includes the division item and the compression item.

### (Feature 12)

The data processing device according to Feature 11, wherein the partial data generation unit divides the compression target data in units of the records included in the compression target data.

### (Feature 13)

The data processing device according to Feature 12, wherein the partial data includes one or more of the records among the plurality of records included in the compression target data.

### (Feature 14)

The data processing device according to Feature 11, wherein the compressed partial data generation unit generates the compressed partial data for each of the partial data, based on the number of the records having the same value of the compression item among the records included in the partial data.

### (Feature 15)

The data processing device according to Feature 14, wherein

the partial data generation unit rearranges, in the compression target data, an order of storing the records included in the compression target data, based on the value of the compression item, and

the compressed partial data generation unit generates the compressed partial data, based on the number of repetitions of the records having the same value of the compression item in the compression target data.

### (Feature 16)

The data processing device according to Feature 11, wherein

the plurality of items includes a dictionary item,

the compressed partial data generation unit determines a corresponding dictionary value for each value of the dictionary item included in the partial data, and generates the compressed partial data by replacing the value of the dictionary item included in the partial data with the corresponding dictionary value, and

a data length of the dictionary value is shorter than a data length of the corresponding value of the dictionary item.

### (Feature 17)

The data processing device according to Feature 16, wherein the storage unit stores dictionary data in which the value of the dictionary item is associated with the dictionary value corresponding to the value of the dictionary item.

### (Feature 18)

The data processing device according to Feature 17, wherein

the compressed data generation unit calculates an offset value from a predetermined position of the compressed data for each of the plurality of the compressed partial data, and

the compressed data includes the offset value for each of the plurality of the compressed partial data.

### (Feature 19)

The data processing device according to Feature 18, wherein the compressed data includes the compressed partial data for each of the partial data and the dictionary value.

### (Feature 20)

The data processing device according to Feature 18, wherein the storage unit stores index data in which the value of the division item included in the partial data is associated with the offset value of the compressed partial data corresponding to the partial data.

### (Feature 21)

The data processing device according to Feature 11, wherein

the compression target data is sales data of a store that sells a plurality of products to a customer,

the record includes a product code that specifies a product purchased by the customer and a purchase quantity of the product purchased by the customer,

the division item is the product code, and

the compression item is the purchase quantity.

### (Feature 22)

The data processing device according to Feature 21, wherein a value of the purchase quantity includes a natural number other than 1.

### (Feature 23)

The data processing device according to Feature 21, wherein the value of the purchase quantity includes a multiple of 6.

### (Feature 24)

A data processing program including causing a computer to function as the data processing device according to Feature 11.

### (Feature 25)

A data processing method executed by a device having a storage unit (e.g., the storage unit 2) storing compression target data including a plurality of records, the data processing method comprising the step of

generating partial data by dividing the compression target data into a plurality of partial data, based on a value of a division item included in the compression target data stored in the storage unit;

generating compressed partial data for each of the partial data, based on a value of a compression item included in the partial data; and

generating compressed data corresponding to the compression target data, based on the compressed partial data, wherein

each of the records includes a value for each of a plurality of items, and

the plurality of items includes the division item and the compression item.

### REFERENCE SIGNS LIST

1 Data processing device
2 Storage unit
3 Partial data generation unit
4 Compressed partial data generation unit
5 Compressed data generation unit
D1 Compression target data (Receipt data)
D2 Partial data
D3 Compressed partial data
D4 Dictionary data
D5 Index data
D6 Compressed data

1. A data processing device for processing transaction data including a plurality of records, the data processing device comprising:
a storage unit that stores the transaction data; and
a compressed data generation unit configured to generate compressed data corresponding to the transaction data, based on a value of a transaction quantity included in the transaction data stored in the storage unit, wherein
each of the records includes a value of at least one item, and
the item includes the transaction quantity.

2. The data processing device according to claim 1, wherein the value of the transaction quantity includes a multiple of 6.

3. The data processing device according to claim 1, wherein the compressed data generation unit generates the compressed data, based on the number of the records having the same value of the transaction quantity among the records included in the transaction data.

4. The data processing device according to claim 3, wherein
the compressed data generation unit rearranges, in the transaction data, an order of storing the records included in the transaction data, based on the value of the transaction quantity, and
generates the compressed data, based on the number of repetitions of the records having the same value of the transaction quantity in the transaction data.

5. The data processing device according to claim 4, wherein
the plurality of items includes a dictionary item,
the compressed data generation unit determines a corresponding dictionary value for each value of the dictionary item included in the transaction data, and generates the compressed data by replacing the value of the dictionary item included in the transaction data with the corresponding dictionary value, and
a data length of the dictionary value is shorter than a data length of the corresponding value of the dictionary item.

6. The data processing device according to claim 1 further comprising:
a partial data generation unit configured to divide the transaction data into a plurality of partial data, based on a value of a product code included in the transaction data stored in the storage unit; and
a compressed partial data generation unit configured to generate compressed partial data for each of the partial data, based on the value of the transaction quantity included in the partial data, wherein
the item includes the product code, and
the compressed data generation unit generates the compressed data, based on the compressed partial data.

7. The data processing device according to claim 6, wherein the compressed partial data generation unit generates the compressed partial data for each of the partial data, based on the number of the records having the same value of the transaction quantity among the records included in the partial data.

8. The data processing device according to claim 7, wherein
the partial data generation unit rearranges, in the transaction data, the order of storing the records included in the transaction data, based on the value of the transaction quantity, and
the compressed partial data generation unit generates the compressed partial data, based on the number of repetitions of the records having the same value of the transaction quantity in the transaction data.

9. A non-transitory storage medium storing a data processing program executable on a computer to cause the computer to function as the data processing device according to claim 1.

10. A data processing method executed by a device having a storage unit storing transaction data including a plurality of records, the data processing method comprising the step of generating compressed data corresponding to the transaction data, based on a value of the transaction quantity included in the transaction data stored in the storage unit, wherein
each of the records includes a value of at least one item, and
the item includes a transaction quantity.

11. A data processing device for processing compression target data including a plurality of records, the data processing device comprising:
a storage unit that stores the compression target data;
a partial data generation unit configured to divide the compression target data into a plurality of partial data, based on a value of a division item included in the compression target data stored in the storage unit;
a compressed partial data generation unit configured to generate compressed partial data for each of the partial data, based on a value of a compression item included in the partial data; and
a compressed data generation unit configured to generate compressed data corresponding to the compression target data, based on the compressed partial data, wherein
each of the records includes a value for each of a plurality of items, and
the plurality of items includes the division item and the compression item.

12. The data processing device according to claim 11, wherein the partial data generation unit divides the compression target data in units of the records included in the compression target data.

13. The data processing device according to claim 12, wherein the partial data includes one or more of the records among the plurality of records included in the compression target data.

14. The data processing device according to claim 11, wherein the compressed partial data generation unit generates the compressed partial data for each of the partial data, based on the number of the records having the same value of the compression item among the records included in the partial data.

15. The data processing device according to claim 14, wherein
the partial data generation unit rearranges, in the compression target data, an order of storing the records included in the compression target data, based on the value of the compression item, and
the compressed partial data generation unit generates the compressed partial data, based on the number of repetitions of the records having the same value of the compression item in the compression target data.

16. The data processing device according to claim 11, wherein
the plurality of items includes a dictionary item,
the compressed partial data generation unit determines a corresponding dictionary value for each value of the dictionary item included in the partial data, and generates the compressed partial data by replacing the value of the dictionary item included in the partial data with the corresponding dictionary value, and
a data length of the dictionary value is shorter than a data length of the corresponding value of the dictionary item.

17. The data processing device according to claim 16, wherein the storage unit stores dictionary data in which the value of the dictionary item is associated with the dictionary value corresponding to the value of the dictionary item.

18. The data processing device according to claim 17, wherein
the compressed data generation unit calculates an offset value from a predetermined position of the compressed data for each of the plurality of the compressed partial data, and
the compressed data includes the offset value for each of the plurality of the compressed partial data.

19. The data processing device according to claim 18, wherein the compressed data includes the compressed partial data for each of the partial data and the dictionary value.

20. The data processing device according to claim 18, wherein the storage unit stores index data in which the value of the division item included in the partial data is associated with the offset value of the compressed partial data corresponding to the partial data.

21. The data processing device according to claim 11, wherein
the compression target data is sales data of a store that sells a plurality of products to a customer,
the record includes a product code that specifies a product purchased by the customer and a purchase quantity of the product purchased by the customer,
the division item is the product code, and
the compression item is the purchase quantity.

22. The data processing device according to claim 21, wherein a value of the purchase quantity includes a natural number other than 1.

23. The data processing device according to claim 21, wherein the value of the purchase quantity includes a multiple of 6.

24. A non-transitory storage medium storing a data processing program executable on a computer to cause the computer to function as the data processing device according to claim 11.

25. A data processing method executed by a device having a storage unit storing compression target data including a plurality of records, the data processing method comprising the steps of:
generating partial data by dividing the compression target data into a plurality of partial data, based on a value of a division item included in the compression target data stored in the storage unit;
generating compressed partial data for each of the partial data, based on a value of a compression item included in the partial data; and
generating compressed data corresponding to the compression target data, based on the compressed partial data, wherein
each of the records includes a value for each of a plurality of items, and
the plurality of items includes the division item and the compression item.

26. The data processing device according to claim 1, wherein the value of the transaction quantity includes a natural number other than 1.

27. The data processing method according to claim 10, wherein the value of the transaction quantity includes a natural number other than 1.
